(19) United States
(12) Patent Application Publication
(10) Pub. No.: US 2022/0113772 A1
(43) Pub. Date: Apr. 14, 2022

(54) EXTENDED SYSTEM BOARDS FOR POWER DISTRIBUTION

(71) Applicant: HEWLETT-PACKARD DEVELOPMENT COMPANY, L.P., Spring, TX (US)

(72) Inventors: Tom J. Searby, Fort Collins, CO (US); Marcus Benzel, Fort Collins, CO (US)

(21) Appl. No.: 17/068,510

(22) Filed: Oct. 12, 2020

(51) Int. Cl. G06F 1/18; H05K 1/02

(52) U.S. Cl. CPC G06F 1/189; H05K 1/0296; H05K 2201/09063; H05K 2201/093; H05K 2201/09027

(57) ABSTRACT

In example implementations, a system board is provided. The system board includes a printed circuit board and an extended portion. The printed circuit board includes an electrical connection to a processor of a computing system. The extended portion is to redistribute power. The extended portion includes a connection to connect to a power supply unit and a plurality of power connections. The plurality of power connections are located along an edge of the extended portion to connect wiring to other components within the computing system and deliver power from the power supply unit to the other components.

### BACKGROUND

Computing systems may include various components to perform various functions. For example, computing systems may include central processors, system memory, a graphics processor, various add-in cards and modules, storage devices, and the like. Each component draws power to operate and perform the respective functions.

In some computer systems, the power supply units may be wired to a system board. The system board may then redistribute power to the various components with additional wiring.

### BRIEF DESCRIPTION OF THE DRAWINGS

FIG. 1 is a block diagram of an example computer system with an extended system board for power distribution of the present disclosure;

FIG. 2 is a block diagram of an example top view of an extended system board of the present disclosure;

FIG. 3 is a block diagram of an example top view of the extended system board with a connected power supply unit of the present disclosure;

FIG. 4 is a block diagram of an example side view of the extended system board with wiring to other components within a housing of the present disclosure; and

FIG. 5 is a block diagram of another example of the extended system board for power distribution of the present disclosure.

### DETAILED DESCRIPTION

Examples described herein provide an extended system board for power distribution within a computing system. As noted above, a computing system may include various components to perform various functions. For example, a computing system may include a central processor, system memory, a graphics processor, various optional add-in cards and modules, storage devices, and the like. Each component draws power to operate and perform the respective functions.

In some computer systems, the power supply units may be wired to a system board. The system board may then redistribute power to the various components with additional wiring. However, there may be a large number of wires within a limited amount of space of a housing that may cause the wires to be stacked on top of one another. As a result, the wires can block airflow from the fans of the power supply units and create airflow issues, potential overheating issues, and the like.

The present disclosure provides an extended system board for power distribution that reduces the amount of wiring and/or relocates the wiring. The extended system board may redistribute power connections on an extended portion of the system board. The power supply unit may be directly connected to the extended portion of the system board, and wiring from the system board to the other components may be located along a single plane. As a result, airflow within the housing of the computing system may be improved, and the wiring to distribute power to other components may be simplified.

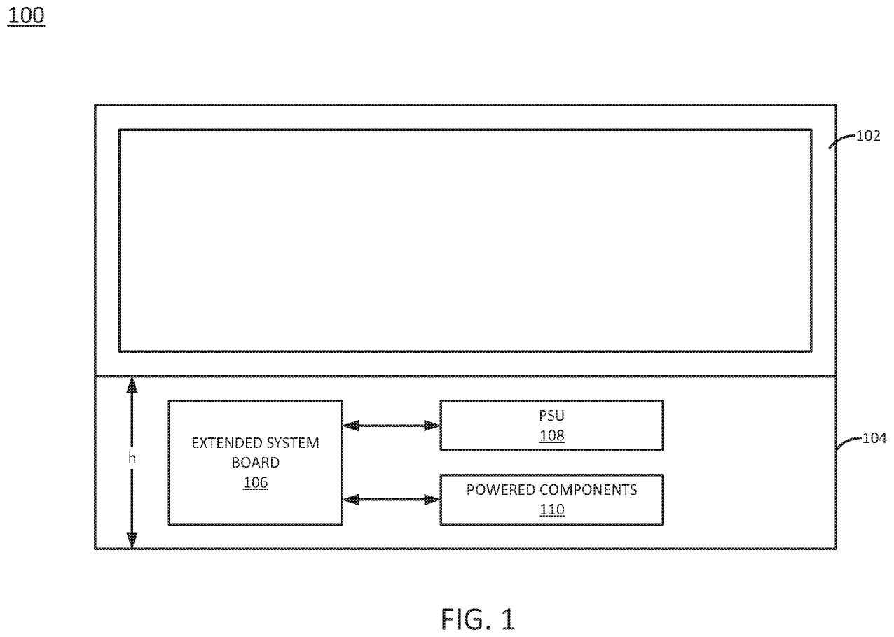

FIG. 1 illustrates an example computing system 100 with an extended system board 106 of the present disclosure. The computing system 100 may be a desktop computer, a laptop computer, a tablet computer, an all-in-one computer, and the like. The computing system 100 has been simplified for ease of explanation and may include additional components that are not shown. For example, the computing system 100 may include input devices (e.g., a keyboard, a mouse, a trackpad, and the like), communication interfaces (e.g., a wireless radio, universal serial bus (USB) ports, and the like), and other components that are not shown.

In an example, the computing system 100 may include a display 102 to display text, graphical images, videos, and so forth. The computing system 100 may include a housing 104 that has a height “h” as shown in FIG. 1. The housing 104 may enclose the extended system board 106 of the present disclosure, a power supply unit (PSU) 108, and powered components 110. The PSU 108 and the powered components 110 may be connected to the extended system board 106. The PSU 108 may provide power that is distributed via connections on the extended system board 106 to the powered components 110.

In an example, the PSU 108 may be a power supply that powers the computing system 100. The PSU 108 may convert alternating current (AC) power into a low voltage regulated direct current (DC) power used by the powered components 110.

In an example, the powered components 110 may include any component within the computing system 100 that operates with power supplied by the PSU 108. The powered components 110 may include a memory, a graphics processor, optional add-in cards and modules, storage devices, and the like.

As housings of computing systems become thinner and smaller, the wiring within the housing can consume more space. As noted above, the wiring between components within the housing and the system board can consume much of the volume within the housing. The wiring can be stacked on top of one another, creating a wall between the system or the PSU fans and components on the extended system board. This “wall of wiring” can restrict airflow and make it difficult to prevent some heat sensitive components within the housing from overheating and malfunctioning.

The extended system board 106 of the present disclosure may allow the wiring to be eliminated or arranged in such a way as to prevent the “wall of wiring.” As a result, air flow may be less restricted, and the temperature of components may be more easily controlled.

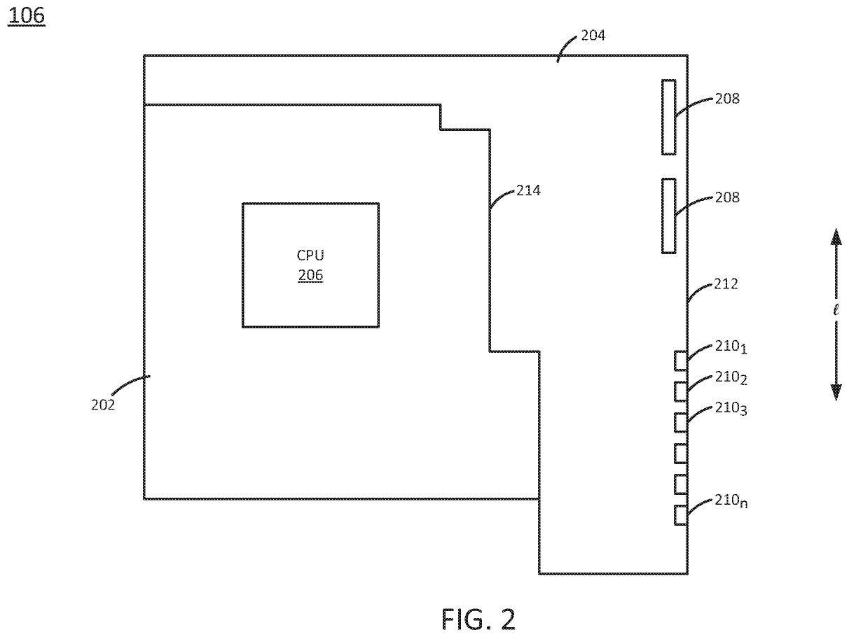

FIG. 2 illustrates an example of the extended system board 106 of the present disclosure. In an example, the extended system board 106 may include a printed circuit board (PCB) 202. The PCB 202 may include electrical connections including connections for a central processing unit (CPU) or processor 206. It should be noted that the PCB 202 has been simplified for ease of explanation and may include many electrical connections that are formed in the PCB 202 that are not shown. The PCB 202 may also include various signaling lines that are formed in the PCB 202 that are not shown.

In an example, an extended portion 204 may be formed around a periphery of PCB 202. The extended portion 204 may also be a printed circuit board. The extended portion 204 may be formed as part of the PCB 202. In other words, the extended portion 204 and the PCB 202 may be fabricated as a single piece.

The extended portion 204 may include an edge 212 that includes a power supply unit connector 208 and a plurality of power connections 210₁ to 210ₙ (hereinafter also referred to individually as a power connection 210 or collectively as power connections 210). Although two power supply unit connectors 208 are illustrated in FIG. 2, it should be noted that any number of power supply unit connectors 208 may be deployed (e.g., including one or more than two).

The power supply unit connector 208 may be a physical or mechanical connector. For example, the power supply unit connector 208 may be a blind mate connector. The power connections 210 may include physical or mechanical connections that allow powered components within the computing system 100 to be connected to the PSU 108 to receive power.

In an example, the edge 212 may be sized to be sufficient to include a desired number of power supply unit connectors 208 and power connections 210. For example, a length “l” of the edge 212 may be fabricated to any desired length.

In an example, extended system board 106 may include a demarcation 214 between the PCB 202 and the extended portion 204. The demarcation 214 may allow the extended portion 204 to be removed from the PCB 202 for different deployments within housings of computing systems that cannot fit the extended portion 204. As a result, a single extended system board 106 can be used for different computing systems with different housings for different wiring layouts. This may reduce manufacturing costs and inventory costs for the extended system board 106.

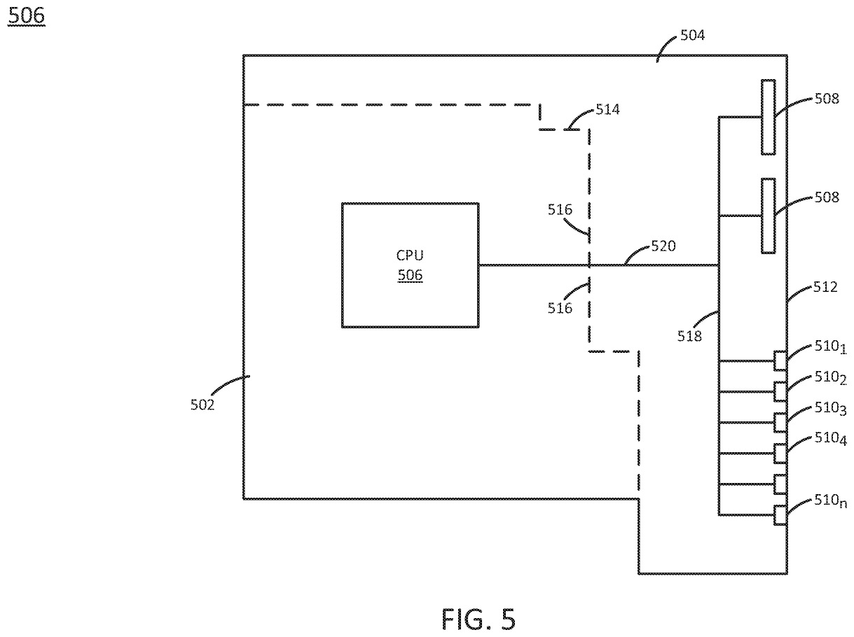

In an example, the demarcation 214 may be a printed line or marking that indicates where the extended portion 204 should be cut away with a cutting tool to be removed. As shown in FIG. 5, and discussed in further details below, the demarcation 214 may be a perforation that may allow the extended portion 204 to be broken away by hand rather than by using a cutting tool.

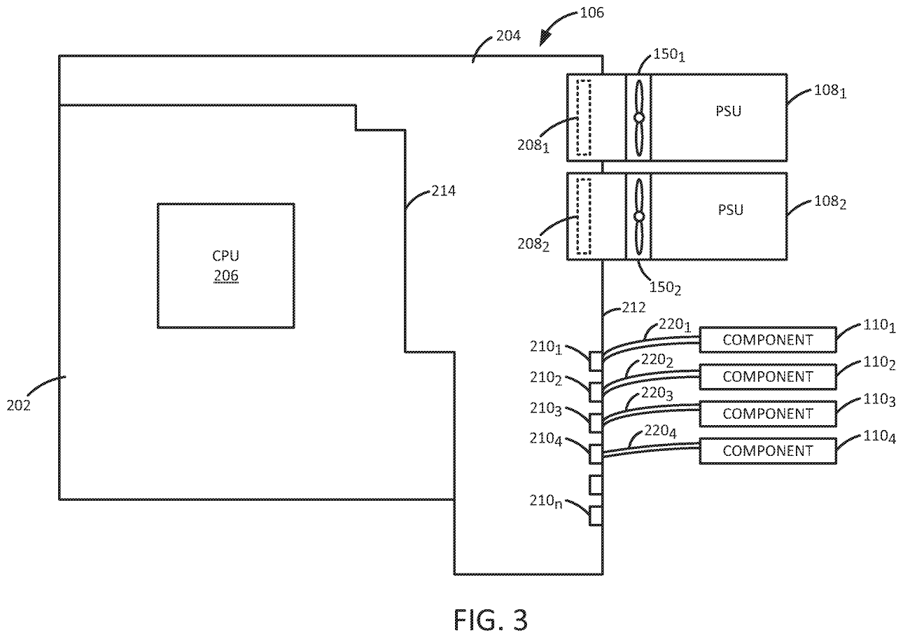

FIG. 3 illustrates a top view of an example of the extended system board 106 connected to PSUs 108₁ and 108₂ and components 110₁ to 110₄. As shown in FIG. 3, the PSU 108₁ may be directly connected to the extended portion 204 of the extended system board 106 via the power supply connector 208₁ shown in phantom below the PSU 108₁. The PSU 108₂ may be directly connected to the extended portion 204 of the extended system board 106 via the power supply connector 208₂ shown in phantom below the PSU 108₂.

The PSUs 108, and 108₂ may include fans 150₁ and 150₂, respectively. The fans 150₁ and 150₂ may generate air flow to help cool the PSUs 108₁ and 108₂. The fans 150₁ and 150₂ may also generate air flow that moves within the housing 104 to cool the CPU 206, the components 110₁ to 110₄, as well as other components that are not shown.

Although the fans 150₁ and 150₂ are illustrated as being near the PSUs 108₁ and 108₂, it should be noted that the fans 150₁ and 150₂ may be located anywhere around the extended system board 106 to cool the components 110₁ to 110₄, the CPU 206, and the like. For example, the fans 150₁ and 150₂ may be located to the right of the PSUs 108 and the components 110, to the left of the extended system board 106, or anywhere in between. In an example, hot air flow generated from air heated from cooling the PSUs 108₁ and 108₂ may be ducted away from the other components (e.g., the components 110, the CPU 206, and the like).

In addition, although two fans 150₁ and 150₂ are illustrated in FIG. 3, it should be noted that any number of fans may be deployed. For example, some fans may be near the PSU 108₁ and 108₂ and other fans may be located around the PCB 202.

The components 110₁ to 110₄ may be connected to respective power connections 210₁ to 210₄ of the extended portion 204. The components 110₁ to 110₄ may be connected via respective wires 220₁ to 220₄. The edge 212 may be located along a side that is closest to the PSUs 108₁ and 108₂ and the components 110₁ to 110₄. This may minimize the amount of wiring that is used to connect the power connections 210₁ to 210₄ to the components 110₁ to 110₄.

In an example, the components 110₁ to 110₄ may be any type of component within the computing system 100 that uses power from the PSUs 108₁ and 108₂ to operate. For example, the component 110₁ may be an external graphics processor, the component 110₂ may be a wireless radio, the component 110₃ may be a hard disk drive, the component 110₄ may be an optical drive, and so forth.

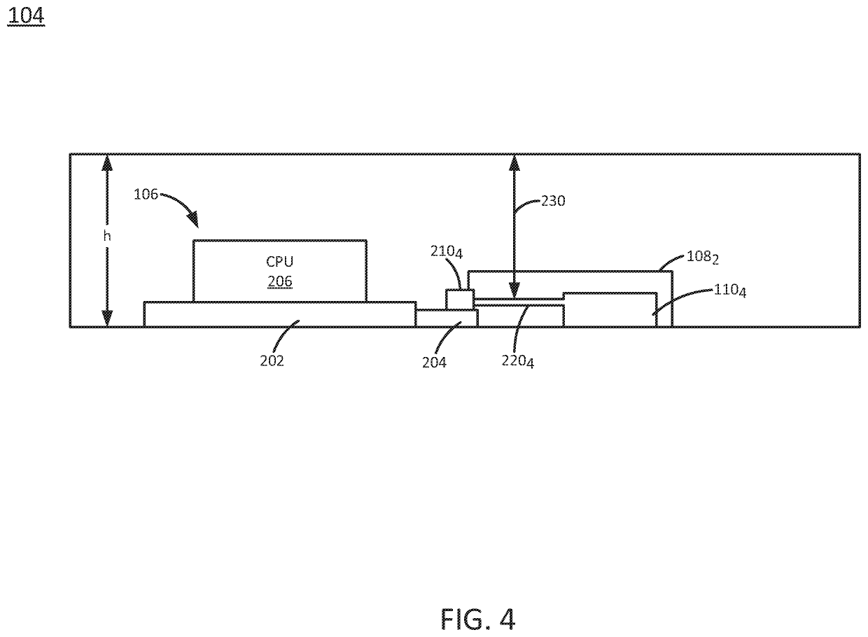

FIG. 4 illustrates a side view of an example of the extended system board 106 within the housing 104. It should be noted that FIG. 4 may not be necessarily drawn to scale.

The power connections 210₁ to 210₄ along a line on the edge 212 of the extended portion 204 may allow the wires 220₁ to 220₄ to be arranged on a common plane. In other words, the wires 220₁ to 220₄ may lie flat on a horizontal plane that is parallel to the PCB 202 and the extended portion 204.

As illustrated in FIG. 4, the side view illustrates how wire 220₄ is visible. Since the wires 220₁ to 220₄ are arranged on a common plane along the edge 212 of the extended portion 204, the other wires 220₁ to 220₃ may not be visible or may be mostly hidden from view by the wire 220₄.

As a result, the arrangement of the connections provided by the extended portion 204 allows more vertical space, as shown by an arrow 230, to be available within the housing 104. As computing systems 100 become thinner and thinner, the amount of height “h” available in the housing 104 is reduced. For example, some housings may have a height as little as 1.7 inches. By arranging the wires 220₁ to 220₄, as shown in FIGS. 3 and 4, more vertical space can be achieved. The vertical space between the PSUs 108₁ and 108₂ and the CPU 206 and other components 110₁ to 110₄ may allow for more effective cooling. The air flow generated by the fans 150₁ and 150₂ may be circulated uninhibited, thereby providing better temperature control within the housing 104.

FIG. 5 illustrates an example of an extended system board 506. The extended system board 506 may include a PCB 502 that includes a CPU 506. The PCB 502 may include additional electrical connections and signaling lines that are formed in the PCB 502 that are not shown.

In an example, the extended system board 506 may include an extended portion 504 that is formed around a periphery of the PCB 502. In an example, the extended portion 504 and the PCB 502 may be formed as a single piece. The extended portion 504 may include an edge 512 that includes power supply unit connectors 508 and power connections 510₁ to 510ₙ (hereinafter also referred to individually as a power connection 510 or collectively as power connections 510). The edge 512 may be located along a side of the extended portion 504 that is closest to other powered components within a housing of a computing system (e.g., the computing system 100).

In an example, a perforation 514 may be formed between a boundary of the PCB 502 and the extended portion 504. The perforation 514 may allow the extended portion 504 to be easily broken off from the PCB 502 for different deployments or form factors. For example, some housings may not have room for the extended portion 504. Thus, the extended portion 504 may be broken off from the PCB 502. Then the PCB 502 may be installed in the housing. The power supply unit may then be connected to the PCB 502 with wires, and additional wires may be used to connect other powered components within the housing.

In another example, the housing may be large enough to provide sufficient air flow while connecting external components (e.g., in a large desktop tower housing). Thus, the extended portion 504 may be broken off from the PCB 502, and the PCB 502 may be inserted into a larger housing. The power supply unit may then be connected to the PCB 502.

In an example, a bus 518 within the extended portion 504 may distribute power from the power supply units connected to the power supply unit connectors 508 to the power connections 510. The power may be distributed to the power connections 510 and other components on the PCB 502 (e.g., the CPU 506) via printed circuits within the extended portion 504 and the PCB 502. Thus, power may be distributed to the power connections 510 and components on the PCB 502 without having to use additional wiring. In an example, a single connection 520 may be used to route power to the CPU 506 or PCB 502. The PCB 502 may then distribute power to necessary components on the PCB 502 via the printed circuits formed within the PCB 502.

The single connection 520 may be located within a gap 516 of the perforations 514. As a result, when the extended portion 504 is removed, the single connection 520 may also be broken. The power supply units and other components can then be connected with additional wiring from the PCB 502, as noted above.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. A system board, comprising:
a printed circuit board comprising an electrical connection to a processor of a computing system; and
an extended portion to redistribute power around a periphery of the printed circuit board, wherein the extended portion comprises:
a connection to a power supply unit; and
a plurality of power connections along an edge of the extended portion to connect wiring to other components within the computing system to deliver power from the power supply unit to the other components.

2. The system board of claim 1, wherein the connection comprises a blind mate connector.

3. The system board of claim 1, wherein the extended portion is located around a periphery of the printed circuit board.

4. The system board of claim 1, wherein the plurality of power connections is located along the edge.

5. The system board of claim 1, wherein the edge is adjacent to the other components.

6. The system board of claim 1, further comprising:
a perforation between the extended portion and the printed circuit board to allow the extended portion to be broken away from the printed circuit board.

7. The system board of claim 1, further comprising:
a marking to outline a shape of the printed circuit board to be installed in a different computing system, wherein the marking is to guide a cut-away of the extended portion.

8. An apparatus, comprising:
a system board comprising an extended portion to redistribute power formed around a periphery of the system board;
a power supply unit coupled to a power supply unit connection on the extended portion; and
a plurality of wires coupled to respective power connections of a plurality of power connections on the extended portion and respective components of a plurality of components, wherein the plurality of wires lies on a common plane.

9. The apparatus of claim 8, wherein the plurality of power connections is located along an edge of the extended portion.

10. The apparatus of claim 9, wherein the edge of the extended portion is closest to the plurality of components.

11. The apparatus of claim 8, wherein the power supply unit connection is located along the edge of the extended portion that has the plurality of power connections.

12. The apparatus of claim 8, further comprising:
a perforation in a printed circuit board of the system board, where the extended portion is connected to the printed circuit board.

13. The apparatus of claim 12, wherein the printed circuit board comprises wiring connectors to connect to the power supply unit when the extended portion is removed from the printed circuit board to be installed in a different computing system.

14. A computing system, comprising:
a system board, comprising an extended portion coupled to a periphery of a printed circuit board to redistribute power, wherein the extended portion comprises a power supply unit connector and a plurality of power connectors;
a power supply unit connected to the power supply unit connector of the extended portion;
a processor electrically coupled to the system board; and
a plurality of power components communicatively coupled to the processor and wired to respective power connectors of the plurality of power connectors of the extended portion to receive power from the power supply unit.

15. The computing system of claim 14, wherein the extended portion is removably coupled to the printed circuit board.

16. The computing system of claim 14, wherein the plurality of power connectors is aligned along an edge of the extended portion.

17. The computing system of claim 16, wherein the edge of the extended portion is formed at a length that is sufficient to include a desired number of the plurality of power connectors.

18. The computing system of claim 16, wherein the power supply unit connector is located on the edge with the plurality of power connectors.

19. The computing system of claim 14, further comprising:
a housing to enclose the system board, the power supply unit, the processor, and the plurality of power components.

20. The computing system of claim 19, wherein the housing comprises a thickness of less than 2 inches.
